(19) United States
(12) Patent Application Publication
(10) Pub. No.: US 2009/0294771 A1
(43) Pub. Date: Dec. 3, 2009

(54) THIN FILM TRANSISTOR ARRAY PANEL HAVING A MEANS FOR ARRAY TEST

(75) Inventors: Beom-Jun KIM, Seoul (KR); Jong-Hwan LEE, Anyang-si (KR); Bum-Ki BAEK, Suwon-si (KR); Sung-Man KIM, Seoul (KR); Hye-Rhee HAN, Suwon-si (KR); Jong-Hyuk LEE, Seoul (KR); Yu-Jun KIM, Incheon (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/183,619

(22) Filed: Jul. 31, 2008

(30) Foreign Application Priority Data
Jun. 3, 2008 (KR) 2008-52202

(51) Int. Cl. H01L 33/00

(52) U.S. Cl. 257/59; 257/E33.001

(57) ABSTRACT

A substrate for a display panel includes a base substrate, a plurality of signal lines, a plurality of signal pads corresponding to first end portions of the signal lines, a shorting bar corresponding to second end portions of the signal lines, a plurality of bridge lines on the base substrate disposed between the signal line and the shorting bar which electrically connects the signal line and the shorting bar. A color filter array panel opposite a TFT LCD panel substrate includes a medium dam layer which fully overlaps the bridge lines of the TFT LCD panel substrate. A data TFT for inspection having a source electrode coupled to the signal line, a drain electrode coupled to any one of the shorting bars, and a gate electrode coupled to a data TFT driving signal line ensures the normal operation of the display panel after the array test.

### BACKGROUND OF THE INVENTION

1. Field of the Invention

The present invention relates to an array substrate and a method of manufacturing the array substrate. More particularly, the present invention relates to an array substrate capable of a defect inspection process after manufacturing the array substrate, and a method of manufacturing the array substrate.

2. Description of the Related Art

Liquid Crystal Displays (“LCDs”) are devices which display images by applying an electric field to a liquid crystal layer disposed between two panels, and regulating the strength of the electric field to adjust a transmittance of light which passes through the liquid crystal layer.

Conventional LCDs include a panel unit having pixels including switching elements and display signal lines, and a gate driving Integrated Circuit (“IC”) which transmits gate signals to gate lines among the display signal lines to turn on and off the switching elements of the pixels, a gray voltage generator which generates a plurality of gray voltages, a data driving IC which applies data voltages to data lines among the display signal lines, and a signal controller which controls the components.

The signal controller and the gray voltage generator are disposed on a printed circuit board (“PCB”) located outside of the panel assembly. The driving IC is mounted on a flexible Tape Carrier Package (“TCP”) located between the PCB and the panel assembly. Generally, two PCBs are provided. In this case, the two PCBs are disposed at upper and left sides of the panel assembly, and the upper and left side PCBs are referred to as gate and data PCBs, respectively. The gate driving IC is disposed between the gate PCB and the panel assembly, and the data driving IC is disposed between the data PCB and the panel assembly. The tape carrier package (“TCP”) is used to dispose both driving ICs. The gate and data driving ICs receive signals from the gate and data PCBs, respectively.

A Chip On Glass (“COG”) type device which attaches a driving IC directly onto the glass substrate using the anisotropic conducting film (“ACF”) without TCP is used to reduce costs. Generally, mobile thin film transistor (“TFT”) LCD devices and compact size TFT LCD devices are produced using the COG type devices.

In order to detect defects such as disconnections and short-circuits during the production of the display device, various test processes are performed. For example, an array test, a visual inspection (“VI”) test, a gross test, and a module test are performed. For these tests, end portions of the gate lines and the data lines are formed as pads having wide ends, in order to improve a contacting property to an external device. In the array test and VI test, the gate lines and the source lines are grouped by certain units (for example, 2G2D or 2G3D) and tested by applying test signals.

### BRIEF SUMMARY OF THE INVENTION

The present invention provides a substrate for a display panel of a display device to detect defect inspection more efficiently.

In an exemplary embodiment, the present invention provides a substrate for a display panel. The substrate including a base substrate, a plurality of first signal lines on the base substrate, the plurality of first signal lines extending in a first direction, a plurality of first signal pads on the base substrate corresponding to first end portions of the plurality of first signal lines, a first shorting bar on the base substrate corresponding to second end portions of the plurality of first signal lines which dissipates an electrostatic charge, the first shorting bar extending in a second direction different from the first direction. The substrate further includes a plurality of bridge lines on the base substrate disposed between the first signal line and the first shorting bar, which electrically connects the first signal line and the first shorting bar together.

According to an exemplary embodiment, the plurality of first signal lines includes a plurality of odd numbered first signal lines and a plurality of even numbered first signal lines electrically connected to the shorting bar.

According to an exemplary embodiment, the first shorting bar includes a first shorting bar line and a second shorting bar line each extended in a second direction parallel to each other, and the first shorting bar line and the second shorting bar line are connected to the plurality of odd and even numbered first signal lines, alternatively.

According to another exemplary embodiment, the plurality of first signal lines are formed on a different layer than the shorting bar, the shorting bar is formed simultaneously with gate metal layers.

According to an exemplary embodiment, the plurality of first signal lines corresponds to data lines that carry data signal into the panel.

According to an exemplary embodiment, the bridge lines are made of transparent conducting oxide including Indium Tin Oxide, Tin Oxide, and Indium Zinc Oxide.

According to an exemplary embodiment, the substrate further includes a first inspection contact hole which electrically connects the first signal line with the bridge line and a second inspection contact hole which electrically connects the shorting bar with the bridge line.

In another exemplary embodiment, the present invention provides a substrate for a display panel including a base substrate, a plurality of first signal lines on the base substrate, the plurality of first signal lines extending in a first direction, a plurality of first signal pads on the base substrate corresponding to first end portions of the plurality of first signal lines, a first shorting bar on the base substrate corresponding to second end portions of the plurality of first signal lines, which dissipates an electrostatic charge, the first shorting bar extending in a second direction different from the first direction, a plurality of bridge lines on the base substrate disposed between the first signal line and the first shorting bar which electrically connects the first signal and the first shorting bar, a plurality of data thin film transistor driving signal lines formed on the base substrate connected to a off voltage applying terminal, a data thin film transistor (“TFT”) for inspection having a source electrode coupled to the first signal line, a drain electrode coupled to any one of the first shorting bar and a gate electrode coupled to the data thin film transistor driving signal line.

In another exemplary embodiment, the present invention provides a display panel including a first base substrate, a plurality of first signal lines on the first base substrate, the plurality of first signal lines extending in a first direction, a plurality of first signal pads on the first base substrate corresponding to first end portions of the plurality of first signal lines, a first shorting bar on the base substrate corresponding to second end portions of the plurality of first signal lines, which dissipates an electrostatic charge, the first shorting bar extending in a second direction different from the first direction, a plurality of bridge lines on the base substrate disposed between the first signal line and the first shorting bar which electrically connects, a second base substrate opposite the first substrate, and a medium dam layer formed on the second substrate that fully overlaps the bridge lines of the first base substrate.

### BRIEF DESCRIPTION OF THE DRAWINGS

The above and/or other aspects, features, and advantages of the present invention will become more apparent from the following detailed description when taken in conjunction with the accompanying drawings, in which:

FIG. 1 is a plan view illustrating an exemplary embodiment of a substrate for a display panel according to the present invention.

FIG. 2 is a plan view illustrating another exemplary embodiment of a substrate for a display panel according to the present invention;

FIG. 3 is an enlarged plan view illustrating the bridge line of FIG. 2 according to the present invention;

FIG. 4 is an enlarged plan view illustrating the bridge line of FIG. 1 and a medium dam layer according to the present invention;

FIG. 5 is a cross-sectional view of FIG. 4 according to the present invention.

FIG. 6 is a plan view illustrating an exemplary embodiment of a substrate for a display panel according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

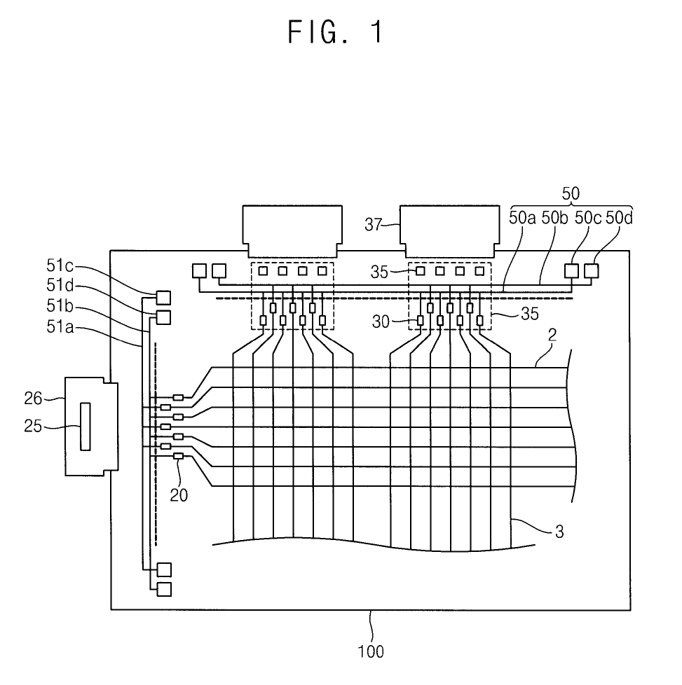

FIG. 1 is a TFT LCD plan view schematically illustrating a portion of a panel unit having gate driving ICs 20 and data driving ICs 30 in which only data driving ICs 30 are attached on a panel assembly as a chip on glass (COG) type.

As shown in FIG. 1, input pad 20, 33, output pad 20, 30 and shorting bar 50a, 50b are formed in the pad region of the TFT array substrate that is not covered with color filter substrate.

Input pads 20, 33 are in contact with flexible films which are made of organic material transmit control signals, power signals, and data signals into the driving IC. Furthermore the driving IC drives at least one of the gate line 2 and data line 3. The gate driving IC 25 is connected to the gate line 2 so as to output a gate driving signal, and the data driving IC 35 is connected to the data line 3 so as to output a data signal.

Output pads 20, 30 provide driving signals one of the scan signals and data signals generated by the driving IC with the signal line and one of the gate line 2 and data line 3.

In the array test, according to an exemplary embodiment of the present invention, the odd numbered data lines and even numbered data lines alternate with each other, so that each of the odd numbered data lines is adjacent to each of the even numbered data lines, so that an electrical short defect may be detected between the odd numbered data lines and the even numbered data lines. Therefore, the even numbered gate lines are grouped and the odd numbered lines are grouped. The same process described above may also be applied to the VI process.

The above mentioned array test method is also applied to the gate line as the same method.

After the array test, shorting bar 50a, 50b in a gate pad region is disconnected from the gate line 2 for normal operation of the TFT LCD. According to an exemplary embodiment, glass cutting using a diamond cutting process through the glass cutting line is performed after the array test. Alternatively, according to another exemplary embodiment, an edge grinding process followed by the diamond glass cutting process may be performed.

In the event that the driver IC is directly mounted on the LCD panel, an inspection process is performed before the data driver is mounted on the LCD panel so as to inspect whether or not the LCD panel is operating normally. In detail, the shorting bar 50 is formed above the pad region of the TFT array substrate in order to conduct the defect inspection process including line defect, pixel defect, and so on. The shorting bar is finally disconnected from the signal line by laser trimming on a fixed width for driving individual driving signals into the signal line before attaching the driver IC. The driving IC is attached to the disconnected region. According to an exemplary embodiment, as the size of the TFT LCD device becomes smaller the space between the pad and the signal line becomes smaller, and defects in the signal line are generated due to the effect of the laser trimming process. During the laser trimming process, poor product reliability is caused by the production of polluted particles and the corrosion of metal lines through the cutting plane.

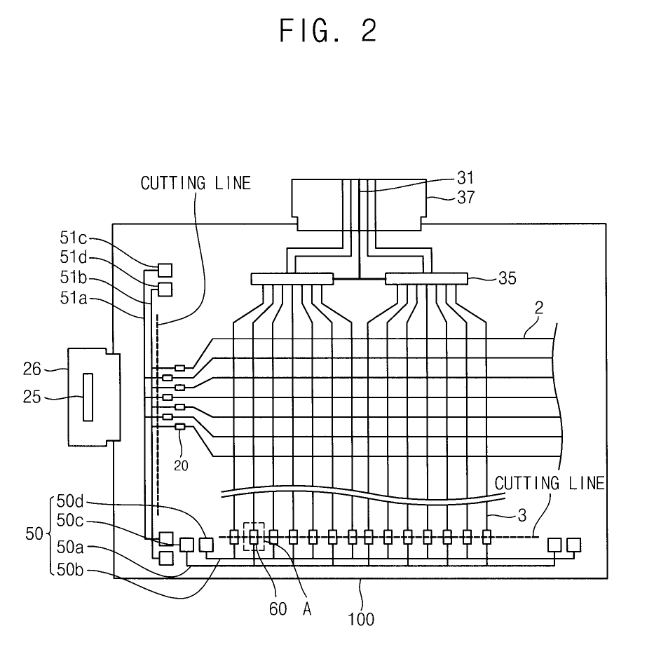

FIG. 2 is a plan view illustrating another exemplary embodiment of a substrate for a display panel according to the present invention;

As shown in FIG. 2, a plurality of gate lines 2 extend in a transverse direction and a plurality of data lines 3 insulated to intersect the gate lines 2 in a longitudinal direction are formed on an insulating substrate 100. A plurality of gate pads 20 connected to gate driving ICs are connected to a first end of the gate lines 2, and a plurality of data pads (not shown) connected to data driving ICs are connected to a second end of the data lines 3. The gate lines 2 and the data lines 3 intersect each other to define a pixel area, a group of the pixel areas form a display area. Other portions other than the display area are defined as a surrounding area.

Data driving ICs 35 are disposed directly on an upper side of the panel as a COG type device, sharing the power signal with each driving IC as a cascade type. In the current exemplary embodiment, COG type devices have driving ICs attached directly onto the glass substrate using the ACF. The COG type device also has flexible printing circuits (“FPCs”) that correspond to a single data driving IC 35. By sharing the specific signal (for example, power signal etc.), however, we can reduce the number of FPCs. Referring back to FIG. 1 a data driving signal is transmitted into the data driving IC 35 attached on the glass substrate through the PCB (not shown) and FPC 37. The repair signal and Vcom signal, however, are directly transmitted into data driving IC 35 attached on the glass substrate from FPC 37.

Gate driving ICs 25, are mounted on a TCP 26 which is located between the PCB (not shown) and the panel assembly. Through TCP 26, a gate driving signal is transmitted into the panel assembly.

Shorting bar 50a, 50b is used for inspection purposes and is connected to a third end opposite the second end of the data line 3. As the resolution of the TFT LCD panel increases, however, the wiring in the pad region becomes complex due to the high level of integration required. Therefore, there is little or no room for piling up shorting bars in the pad region. In an exemplary embodiment of the invention, array test shorting bar 50a, 50b is connected to a third end opposite the second end of the data line 3, located on the opposite side of a data fan out region. By positioning the shorting bar 50a, 50b at this location, it is possible to have high manufacturing yield without defects during an array test. The shorting bar includes an odd shorting bar 50a which is connected to odd data lines 3 and even shorting bar 50b which is connected to even data lines 3. Both of the odd and even shorting bars 50a and 50b are arranged parallel to each other at a fixed interval. In other exemplary embodiments of the invention, shorting bar 50a, 50b is arranged in the data pad region near the fan out region as shown in FIG. 1.

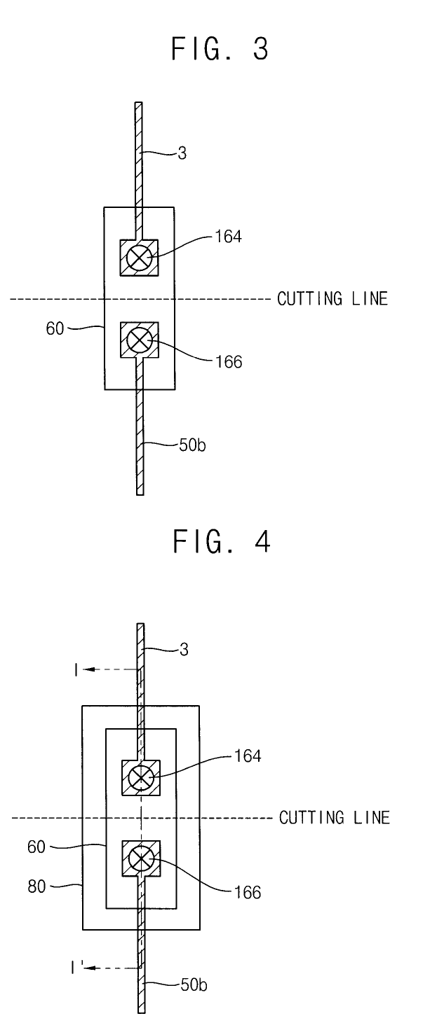

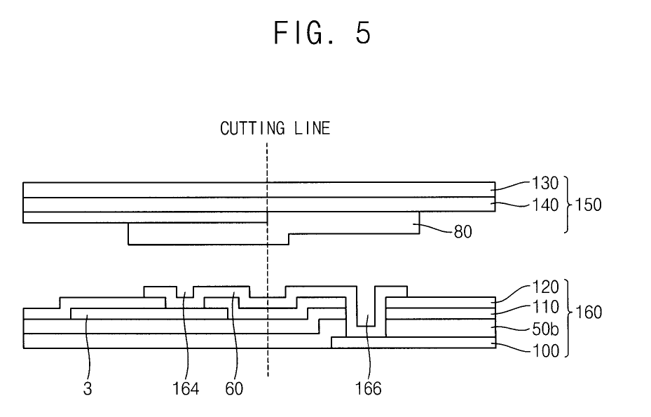

Referring to FIG. 3, the metal layer including data lines 3 are different from the shorting bar 50b which is connected to the data lines 3. Therefore, bridge line 60 links the data lines 3 with the shorting bar 50b for array testing. Bridge lines 60 which are made of a transparent conducting oxide such as Indiun Tin Oxide (ITO) and Indium Zinc Oxide (IZO) electrically link data lines 3 with shorting bar 50a, 50b. That is, odd/even bridge lines 60 are electrically connected to data pad 30 which is exposed through the data contact hole 31 (depicted in FIG. 2, for example). Also, the odd bridge lines 60 are connected with the exposed odd shorting bar 50a through the first inspection contact hole 164 across a gate insulating layer 110 (depicted in FIG. 5) and passivation layer 120 (depicted in FIG. 5). And the even bridge lines 60 are connected with the exposed even shorting bar 50b through the second inspection contact hole 166 across the passivation layer 120.

After the end of array testing, bridge line 60 is disconnected from the data lines 3 through a glass cutting operation to ensure correct operation of the TFT LCD panel. In the event that the data lines 3 and shorting bar 50a, 50b are made of the same metal layers, the cutting edge plane is easily corroded after a laser trimming operation due to the exposure to moisture. Using the bridge line 60, however, the metal corrosion problem could be solved owing to the ITO metal characteristics having strong resistance to corrosion. That is, the cutting line (depicted in FIG. 3, for example) which does not overlap both the data line 3 and the shorting bar 50a, 50b is exactly positioned in the middle of the bridge lines 60. The glass cutting operation is performed through the cutting line, so only the bridge lines 60 are exposed after the glass cutting operation. The gate metal layer includes Cr, MoW, Cr/Al, Cu, Al(Nd), Mo/Al, Mo/Al(Nd), Cr/Al(Nd), for example.

Thus, shorting bar 50a, 50b that is connected to data line 3 through the bridge line 60 made of transparent conducting oxide such as ITO and IZO prohibits the occurrence of static electricity during the manufacturing method of a TFT LCD. Shorting bar 50a, 50b which enables wiring defect testing after manufacturing the TFT array panel allows for easy inspection. After the wiring defect inspection process, the bridge line 60, which links data line 3 to shorting bar 50a, 50b, is scribed using a diamond cutting operation to disconnect shorting bar 50a, 50b with data line 3 electrically for normal operation of the TFT LCD panel.

FIG. 4 is an enlarged plan view illustrating the bridge line of FIG. 1 and a medium dam layer according to the present invention, and FIG. 5 is a cross-sectional view of FIG. 4 according to the present invention.

As shown in FIG. 4, the bridge line further includes a medium dam layer 80. That is, bridge line 60 located in a lower portion of a TFT panel array 160 are overlapped with medium dam layer 80 which is located in a color filter array panel 150 positioned opposite the TFT array panel 160. After performing the wiring defect inspection operation, the bridge line 60 which links data line 3 and shorting bar 50a, 50b is scribed using a diamond cutting operation. During those operations, there is a risk of an electric short between the lower and the higher panel due to the transparent conducting oxide that exists on both sides. So, medium dam layer 80 which is made of the same material as a column spacer (not shown) which maintains a space between the TFT array panel 160 and the color filter array panel 150 is positioned between the lower and the higher panel in the bridge line 60 as a buffer layer.

Further, as shown in FIG. 5, first, on the insulating layer (i.e., the substrate) 100, a gate metal layer is deposited and photo-etched to form the gate line 2 and shorting bar 50a, 50b, which can be formed as double layers. For example, according to an exemplary embodiment, a Cr or Mo alloy having desirable physicochemical characterstics is deposited to form a first layer, and then, Al or Ag alloy having a small resistance is deposited to form a second layer on the first layer. Next, the gate insulating layer 110 made of SiNx is deposited approximately 1,500-5,000 Å thick using a chemical vapor deposition, and then, a data metal layer is deposited to form a data line 3. According to an exemplary embodiment, the data metal may be formed as triple layers. For example, Cr or Mo alloy layer having desirable physicochemical characteristics is deposited to form a first layer and third layer, and then, Al or Ag alloy having a small resistance is deposited to form a second layer on the first layer. The metal layers can be deposited by, for example, a sputtering method. A passivation layer 120 is then formed by depositing an inorganic insulating layer such as SiNx, SiOx, etc., or by coating an organic insulating layer or by growing a-Si:C:O film or a-Si:O:F film by a chemical vapor deposition. In the current exemplary embodiment, a-Si:C:O film or a-Si:O:F film is an inorganic insulating layer and includes a very low dielectric in a range of approximately 2 to 4. If a-Si:C:O film, SiH(CH₃)₃, SiO₂(CH₃)₄, (SiH)₄O₄(CH₃)₄, Si(C₂H₅O)₄, etc., are used as a basic source, and an oxidant such as N₂O or O₂ and a mixed gas such as Ar or He are flowed to deposit a-Si:C:O. In addition, if a-Si:O:F film is used, a mixture gas of O₂ and SiH₄, SiF₄, etc., is flowed to deposit it. According to an exemplary embodiment, CF₄ may be added as an auxiliary fluoride source. Further, as shown in FIG. 5, the passivation layer 120 is etched to form the first inspection contact hole 164 for exposing the data line 3 and together with the gate insulating layer 110 to form the second inspection contact hole 166 for exposing the shorting bar 50a, 50b. Further, contact holes (not shown) for exposing a gate pad (not shown), a data pad (not shown) and a drain electrode (not shown) are also formed. Next, ITO or IZO having the thickness of 4000 Å to 500 Å is deposited and photo-etched to form bridge lines 60. Also, a pixel electrode of a display area (not shown), an auxiliary gate pad (not shown) connected to the gate pad and an auxiliary data pad (not shown) connected to the data pad are formed during this operation.

In an exemplary embodiment of the invention, the separate color filter array panel 150 which is opposite the TFT array panel 160 with a fixed gap thickness of approximately 5 μm, includes a black matrix 130 made of an organic or metal film, common transparent electrode 140, for example, ITO, IZO, and medium dam layer 80 having a thickness smaller than a cell gap.

The TFT array panel 160 having a completed wiring defect test and color filter array panel 150 which includes a column spacer as a buffer layer in the bridge line region are assembled. And, in accordance with the cutting line the TFT LCD panel is seperated into unit panels using a diamond cutting operation.

Thus, referring now back to FIG. 2, the first wiring test circuit 50 is provided with a test signal for testing the electrical operation state (or continuity) of the source lines formed on the array substrate 100. The first wiring test circuit 50 includes a first wiring test pad 50c, a second wiring test pad 50d, a first wiring test line 50a, and a second wiring test line 50b. The wiring test corresponds to a voltage test. That is, the wiring test may be performed through a voltage compensation or a voltage discrepancy reference setting test. Particularly, according to the 2D mode, a first test signal is applied to the odd numbered source lines through the first wiring test pad 213, and a second test signal is applied to the even numbered source lines through the second wiring test pad 215. The first wiring test line 212 is electrically connected to every odd data line, and the second wiring test line 214 is electrically connected to every even data line, according to the 2D mode.

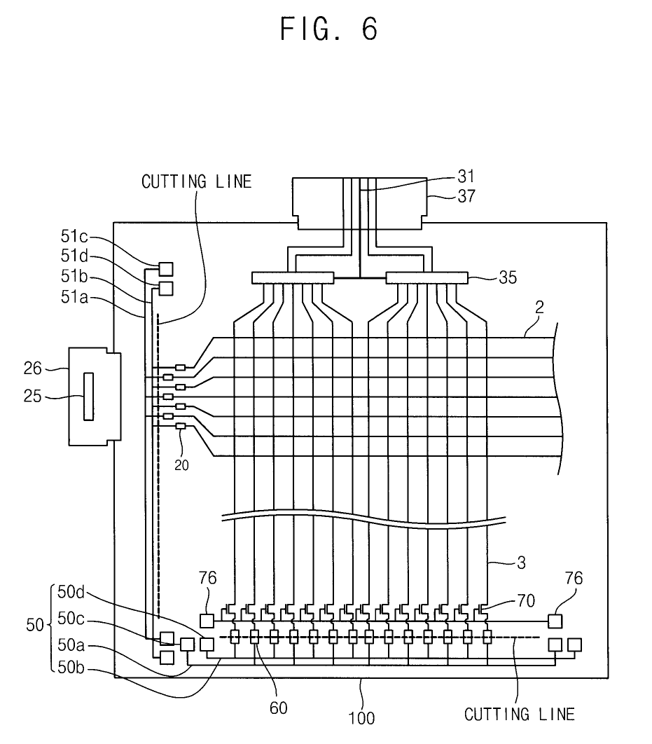

FIG. 6 is a plan view illustrating an exemplary embodiment of a substrate for a display panel according to the present invention.

Referring to FIG. 6, a plurality of gate lines 2 extend in a transverse direction and a plurality of data lines 3 insulated to intersect the gate lines 2 in a longitudinal direction are formed on an insulating substrate 100. A plurality of gate pads 20 connected to gate driving ICs 25 are connected to a first end of the gate lines 2, and a plurality of data pads 30 connected to data driving ICs 35 are connected to a second end of the data lines 3. The gate lines 2 and the data lines 3 intersect each other to define a pixel area, a group of the pixel areas form a display area. A surrounding area is defined as a portion other than the display area.

Data driving ICs 35 are disposed directly on an upper side of the panel as a COG type sharing the power signal with each of the driving ICs as a cascade type. Gate driving ICs 25 are mounted on a TCP 26 which is located between the PCB 36 and the panel assembly.

Shorting bar 50a, 50b for inspection is connected to a third end opposite the second end of the data line 3. In the current exemplary embodiment of the invention, array test shorting bar 50a, 50b is connected to a third end opposite the second end of the data line 3, which is the opposite side of the data fan out region. With this configuration it is possible to have high manufacturing yield without defects during array testing. The shorting bar includes odd shorting bar 50a which is connected to odd data lines 3 and even shorting bar 50b which is connected to even data lines 3. Both the odd and even shorting bars 50a and 50b in some exemplary embodiments of the present invention are arranged parallel to each other at a fixed interval.

The metal layer including data lines 3 are different from shorting bars 50a, 50b which are connected to the data lines 3. Therefore, the ITO bridge line 60 links the data lines 3 with the shorting bar 50a, 50b for array testing. After the array testing is completed, the ITO bridge line 60 is disconnected with data lines 3 using a scribing operation to ensure correct operation of the TFT LCD panel. Using the ITO bridge line 60, however, the metal corrosion problem could be solved owing to the ITO metal characteristics having strong resistance to corrosion. The gate metal layer includes Cr, MoW, Cr/Al, Cu, Al(Nd), Mo/Al, Mo/Al(Nd), Cr/Al(Nd).

A data TFT 70 for inspection is connected to a third end opposite the second end of the data line 3 in series with the ITO bridge line 60. The data TFT 70 is also connected to a shorting bar 50a, 50b and data TFT driving signal line 75. The data line 3, shorting bar 50a, 50b, and the data driving signal line 75 are connected to a source electrode, drain electrode, and gate electrode of the data TFT 70, respectively. The data TFT driving signal line 75 is connected to a data Voff pad 76. All the gate electrodes of the data TFTs 70 are connected to the data Voff pad 76. The Voff pad 76 is kept constant as Voff voltages in a later process. After the array test, the shorting bars 50a, 50b are disconnected with data lines 3 by a diamond-cutting operation in ITO bridge line 60 region for normal TFT LCD operation. The possibility of incoming static electricity into the panel, however, still exists through the cutting edge of the metal wiring. Thus, the data TFTs 70 are always in an off state (i.e., a disconnection state). The data TFTs 70 function as a fail safe for unpredictable inflow of static electricity that causes abnormal operation of a TFT LCD.

While the present invention has been shown and described with reference to some exemplary embodiments thereof, it should by understood by those of ordinary skill in the art that various changes in form and details may be made therein without departing from the spirit and scope of the present invention as defined by the appended claims.

What is claimed is:

1. A substrate for a display panel comprising:
a base substrate;
a plurality of first signal lines on the base substrate, the plurality of first signal lines extending in a first direction;
a plurality of first signal pads on the base substrate corresponding to first end portions of the plurality of first signal lines;
a first shorting bar on the base substrate corresponding to second end portions of the plurality of first signal lines, which dissipates an electrostatic charge, the first shorting bar extending in a second direction different from the first direction;
a plurality of bridge lines on the base substrate disposed between the first signal line and the first shorting bar which electrically connects the first signal line and the first shorting bar together.

2. The substrate of claim 1, wherein the plurality of first signal lines comprises a plurality of odd numbered first signal lines and a plurality of even numbered first signal lines electrically connected to the first shorting bar.

3. The substrate of claim 2, wherein the first shorting bar comprises:
a first shorting bar line and a second shorting bar line each extended in a second direction parallel to each other, and
wherein the first shorting bar line and the second shorting bar line are connected to the plurality of odd and even numbered first signal lines, alternatively.

4. The substrate of claim 2, wherein the plurality of first signal lines are formed on a different layer than the first shorting bar, wherein the first shorting bar is formed simultaneously with gate metal layers.

5. The substrate of claim 2, wherein the plurality of first signal lines corresponds to data lines which carry data signal into the display panel.

6. The substrate of claim 5, wherein the plurality of first signal lines are formed on a different layer than the first shorting bar, wherein the first shorting bar is formed simultaneously with gate metal layers.

7. The substrate of claim 1 wherein the bridge lines are made of transparent conducting oxide comprising Indium Tin Oxide, Tin Oxide, and Indium Zinc Oxide.

8. The substrate of claim 7, further comprising:
a first inspection contact hole which electrically connects the first signal line with the bridge line and a second inspection contact hole which electrically connects the first shorting bar with the bridge line.

9. A substrate for a display panel comprising:
a base substrate;
a plurality of first signal lines on the base substrate, the plurality of first signal lines extending in a first direction;
a plurality of first signal pads on the base substrate corresponding to first end portions of the plurality of first signal lines;
a first shorting bar on the base substrate corresponding to second end portions of the plurality of first signal lines, which dissipates an electrostatic charge, the first shorting bar extending in a second direction different from the first direction;
a plurality of bridge lines on the base substrate disposed between the first signal line and the first shorting bar which electrically connects the first signal line and the first shorting bar together;
a plurality of data thin film transistor driving signal lines formed on the base substrate connected to a off voltage applying terminal;
a data thin film transistor for inspection having a source electrode coupled to the first signal line, a drain electrode coupled to the first shorting bar and a gate electrode coupled to the data thin film transistor driving signal line.

10. The substrate of claim 10, wherein the plurality of first signal lines comprises a plurality of odd numbered first signal lines and a plurality of even numbered first signal lines electrically connected to the first shorting bar.

11. The substrate of claim 10, wherein the first shorting bar comprises:
a first shorting bar line and a second shorting bar line each extended in a second direction substantially parallel to each other, and
wherein the first shorting bar line and the second shorting bar line are connected to the plurality of odd and even numbered first signal lines alternatively.

12. The substrate of claim 10, wherein the plurality of first signal lines are formed on a different layer than the first shorting bar, wherein the first shorting bar is formed simultaneously with gate metal layers.

13. The substrate of claim 10, wherein the plurality of first signal lines corresponds to data lines which carry data signal into the panel.

14. The substrate of claim 13, wherein the plurality of first signal lines are formed on a different layer than the first shorting bar, wherein the first shorting bar is formed simultaneously with gate metal layers.

15. The substrate of claim 9 wherein the bridge lines are made of transparent conducting oxide comprising Indium Tin Oxide, Tin Oxide, and Indium Zinc Oxide.

16. The substrate of claim 15, further comprising a first inspection contact hole which electrically connects the first signal line with the bridge line and a second inspection contact hole which electrically connects the first shorting bar with the bridge line.

17. The substrate of claim 9, wherein the data thin film transistor is connected with the bridge lines in series along the first signal line which is opposite end of a signal pad region of a first signal pad.

18. A display panel comprising:
a first base substrate;
a plurality of first signal lines on the first base substrate, the plurality of first signal lines extending in a first direction;
a plurality of first signal pads on the first base substrate corresponding to first end portions of the plurality of first signal lines;
a first shorting bar on the first base substrate corresponding to second end portions of the plurality of first signal lines, which dissipates an electrostatic charge, the first shorting bar extending in a second direction different from the first direction;
a plurality of bridge lines on the first base substrate disposed between the first signal line and the first shorting bar, which electrically connects the first signal line and the first shorting bar;
a second base substrate opposite the first base substrate; and
a medium dam layer formed on the second base substrate which fully overlaps the bridge lines of the first base substrate.

19. The display panel of claim 18, wherein the plurality of first signal lines comprises a plurality of odd numbered first signal lines and a plurality of even numbered first signal lines electrically connected to the shorting bar.

20. The display panel of claim 18, wherein the plurality of first signal lines corresponds to data lines which carry data signal into the display panel.

21. The display panel of claim 18, wherein the bridge lines are made of transparent conducting oxide comprising Indium Tin Oxide, Tin Oxide, and Indium Zinc Oxide.

22. The display panel of claim 21, further comprising a first inspection contact hole which electrically connects the first signal line with the bridge line and a second inspection contact hole which electrically connects the first shorting bar with the bridge line.

23. The display panel of claim 9, wherein the data thin film transistor is connected with the bridge lines in series along the first signal line that is opposite end of a signal pad region of a first signal pad.

24. The display panel of claim 18, a column spacer formed on the second base substrate to maintain a space between the first and second base substrates.

25. The display panel of claim 24, wherein the medium dam layer is of a same material as the column spacer and is formed simultaneously with the column spacer layer.
